(19) United States
(12) Patent Application Publication
(10) Pub. No.: US 2024/0210490 A1
(43) Pub. Date: Jun. 27, 2024

(54) ELECTRONIC CIRCUIT FOR DETERMINING THE CHARGING STATE OF A BATTERY CELL

(71) Applicant: LISA DRÄXLMAIER GMBH, Vilsbiburg (DE)

(72) Inventor: Dirk LEHMKUHL, Landshut (DE)

(73) Assignee: LISA DRÄXLMAIER GMBH, Vilsbiburg (DE)

(21) Appl. No.: 18/544,873

(22) Filed: Dec. 19, 2023

(30) Foreign Application Priority Data
Dec. 21, 2022 (DE) 10 2022 134 261.1

(51) Int. Cl. G01R 31/396; G01R 31/367; G01R 31/374; G01R 31/3835; G01R 31/389

(52) U.S. Cl. CPC G01R 31/396; G01R 31/367; G01R 31/374; G01R 31/3835; G01R 31/389

(57) ABSTRACT

An electronic circuit for determining a charging state of a battery cell of a battery system. The electronic circuit is configured for obtaining a plurality of measured values of an open-circuit voltage of the battery cell with corresponding time values for which the measured values of the open-circuit voltage have been measured. The electronic circuit is further configured for determining a time up until which a charging state corresponding to an end point voltage of the battery cell is reached on the basis of an analytical solution of a function, which specifies a connection between the open-circuit voltage and the charging state of the battery cell. The electronic circuit is further configured for determining the charging state of the battery cell based on a reverse function of the charging-state dependent time.

### CROSS-REFERENCE TO RELATED APPLICATIONS

This application claims priority to and the benefit of German Patent Application No. 10 2022 134 261.1 filed on Dec. 21, 2022. The disclosure of the above application is incorporated herein by reference.

### FIELD

The present disclosure relates to an electronic circuit for determining a charging state of a battery cell of a battery system based on an analytical solution, and a corresponding method.

### BACKGROUND

The statements in this section merely provide background information related to the present disclosure and may not constitute prior art.

The BMS (battery management system) and the software located therein are used, for example, to calculate the current charging state of the battery (state of charge, SOC) and to carry out a power prediction (state of power, SOP). The accuracy of the SOC and SOP function is of particular importance here. The SOC and SOP function makes possible, for example, the optimal and proper operation of the battery up to the renewed battery charging through an accurate range determination, and inhibits, for example, an immobilization of the vehicle. Inaccuracies in the voltage and current measurement, and tolerances in the capacities of the individual cells of the battery lead to an increasingly inaccurate SOC and SOP determination. In addition, the capacity of the battery steadily decreases due to aging (state of health, SOH) so that the minimum voltage is reached at the same current in ever shorter times during discharging. This can be accordingly improved in a cost-intensive manner only to a limited extent through cell selection and more accurate measuring chips. In specifications, the manufacturer (OEM) usually specifies an SOC accuracy of 2-4% until the end of life (end of life, EOL). For this reason, the SOC must be corrected (recalibrated) repeatedly with appropriate methods. Software processes that make possible a very accurate SOC correction are very computation and memory intensive and are limited due to the available memory (RAM) and the performance of the CPU of the microcontroller.

On the one hand, there have been up to now only calculation and memory intensive, and thus expensive, implementations for a standard model used in the electrochemical model (EM), for example, on a powerful microcontroller. The SOC correction is carried out herein over the entire state range using an extended Kalman filter. The measuring chips that are used, as a rule, are so accurate with respect to the current measurement that an SOC correction for achieving the accuracy mentioned above can be omitted over the entire state range. For the SOP function there are predicted 2, 10, 30-second limiting currents based on characteristic diagrams. The limiting currents are only limited within the lower SOC range so that the end point voltage is not under-stepped. Due to the costs, for example, of the microcontroller (MCU) mentioned above, the previous solution is not economical from the perspective of the OEM with regard to the cost to benefit ratio and is therefore seldom suitable for series production. An exact model for a part-state range is useful for these mentioned reasons.

Equivalent circuit models (ECM models) with one or two RC elements are commonly used during battery state detection for the SOC calculation in connection with the Kalman filter in the known methods. Real-time compatible parameter estimators are also used to take into account the aging-dependent ECM parameters. Methods suitable for serial production based on electrochemical models (EMs) are not currently available. Online parameter estimators are also not currently available. Only so-called digital twins (TWAICE) are known, in which the evaluation of the battery state is performed in a cloud on an external computer. Aging effects of model parameters can also be taken into account here.

Only ECM models are currently used with the SOP function. A differential equation of an ECM model is used here to determine the maximum current up to a lower end point voltage.

### SUMMARY

This section provides a general summary of the disclosure and is not a comprehensive disclosure of its full scope or all of its features.

The present disclosure provides an improved charging state determination of the battery cells of a battery system, for example, for an electric vehicle.

The present disclosure also provides a charging state determination in which the charging state can be determined with high accuracy with low hardware expense.

[symbol]

The present disclosure is based on the idea of illustrating a closed

analytical solution of the physical model using a new special function. specifically used in charging devices with low SOC values in combination with the accurate standard model, so that an improved result between desired SOC and SOP accuracy and hardware requirements can be found.

In one variation, a solution in closed form (or an expression in closed form) is any formula that can be evaluated in a finite number of standard operations. A numerical solution is any approximation that can be evaluated in a finite number of standard operations. Solutions in closed form and numerical solutions are similar in this respect, as both can be evaluated with a finite number of standard operations. They differ in that a closed solution is exact, while a numerical solution is only an approximate one.

The analytical solution provides a very accurate prediction of the limiting currents beyond the usual pulse times of 30 seconds for the SOP function. A Kalman filter that can calculate the values exactly, regardless of the increment, is available for the first time for the SOC calculation for this physical model.

Electrochemical models (EMs) and equivalent circuit models (ECMs) form the model-based methods for establishing a Kalman filter and use of the Kalman filter for SOC calculations. ECMs require little computing power from the microcontroller units (MCUs) and are widely used in real-time applications of battery state algorithms due to their low parameterization effort. However, ECM models usually have limited physical importance, and their validity is limited to the range of their initial parameterization. Conventional ECMs are additionally unable to describe internal physical processes. The Doyle-Fuller-Newman (DFN) model is a popular electrochemical model. The model makes a very accurate description of cell behavior theoretically possible. One disadvantage is, however, a comparatively complex parameter identification process. A reduced model which has only minor additional inaccuracies in particular for lithium iron phosphate cells is inferred in some publications based on the full DFN model.

EM and ECM models are used with the SOC determination via a state observer for the entire operating range. In contrast, only ECM models are used with the SOP function in a lower SOC range. The ECM model has only a limited validity or higher inaccuracy, in particular with low charging states and higher currents. The inventors have discovered using a reduced EM model only for the lower SOC range addresses this issue. This significantly improves the accuracy with lower charging states and higher currents. In addition, the maximum limiting current can be precisely determined even with states that are further removed from the end point voltage. Tabulated values shared by the manufacturer usually take effect here. A current-independent internal resistance of the battery that can also be used for the performance-related aging with the present disclosure can be determined here. The great step forward is that an analytical solution can be inferred for the first time with only insignificant simplifications for the reduced EM. The solution is always exact, and independent from the increment Δh that was needed in the previous solutions. The reduced EM has significantly fewer parameters than in the usual solutions. The present disclosure provides a reduced memory and calculation intensive solution for the SOC determination, and a parameter estimator that can also determine the aging-dependent parameters using the analytical fit functions with a nonlinear regression even in real time online.

A solution for improving a standard cell model (electrochemical model) that provides an expansion of the validity range or the accuracy is presented for the first time with this present disclosure. The present disclosure provides a method to solve this model and discloses a closed and analytical solution for the first time.

This was previously only possible for ECM models with one or 2 RC elements. The complexity of the Kalman filter, and thus the requirement for the hardware on which the application runs, is significantly reduced. An online parameter estimator is therefore possible and appropriate here for the first time. The time horizon of the power prediction (SOP) is greater in comparison to the standard solution, that is, the available power of the battery can be predicted longer with the same accuracy.

A prediction is even realizable where the known solution (ECM model) works with tabulated values that have been published by the manufacturer of the cell. The calculation of a current-independent internal resistance is realizable in this way. In addition, the method presented here also provides other information, such as, for example, the time to a fixed charging state, and end point voltage that is useful for the performance evaluation. A technical advantage is obtained thereby over the use of the known solution.

The method presented here is an alternative in particular for technologies such as LiFePO4, in which the so-called OCV method delivers unsatisfactory results with the SOC recalibration. High hardware costs for a corresponding accurate voltage measurement can be saved here.

An extended Kalman filter is presented which delivers a more accurate SOC, or synonymously is less time and calculation intensive. This can mean a cost advantage when selecting the microcontroller (hardware). According to the prior art, there exist precisely for this reason numerous alternative algorithms to the Kalman filter which, however, use other techniques. A variety of use possibilities thus arise with the method presented herein.

The available memory (RAM) and the performance of the CPU can be improved with the present disclosure, that is, additional and more complex algorithms can be implemented on the BMU (battery management unit) with the same hardware. A more economical chip can be used if the function of a battery core is consistent.

According to a first aspect, the present disclosure provides an electronic circuit for determining a charging state, SOC, of a battery cell of a battery system, in which the electronic circuit is configured for obtaining a plurality of measured values of an open-circuit voltage of the battery cell with corresponding time values for which the measured values of the open-circuit voltage were measured; determining a time up until which a charging state is reached corresponding to an end point voltage of the battery cell based on an analytical solution of a function that indicates a connection between the open-circuit voltage and the charging state of the battery cell; and determining the charging state of the battery cell based on a reverse function of the time dependent from the charging state.

Such an electronic circuit provides an improved determination of the charging state of the battery cells of a battery system, for example, of an electric vehicle. An SOC determination with higher accuracy is possible with the electronic circuit, taking into account the aging with simple calculation-saving methods. As already mentioned above, the available memory (RAM) and the performance of the CPU can be improved with the realization of such an electronic circuit. Additional and more complex algorithms can thus be implemented on the BMU with the same hardware. A more economical chip can be used if the functionality is consistent.

According to one variation of the electronic circuit, the function is based on an electrochemical model of the battery cell.

A significantly more accurate determination of the characteristic values of the battery cell, in particular of the charging state, than with an equivalent circuit of the battery cell, can be carried out with the electrochemical model of the battery cell.

According to one variation of the electronic circuit, the electrochemical model of the battery cell is set for a lower range of the charging state.

The technical advantage is thus achieved that the model is simplified when only the lower range of the charging state is to be observed, that is, fewer parameters are desired, and the calculation complexity is reduced with the use of such a reduced model. Additionally, the evaluation of the lower range of the charging state is sufficient to determine the charging state without negatively affecting the accuracy.

According to one variation of the electronic circuit, the lower range of the charging state comprises charging states below 50 percent.

The inventors have discovered that for an evaluation with the reduced model, a consideration of charging states lower than 50% is sufficient for determining the charging state.

According to one variation of the electronic circuit, the electrochemical model of the battery cell is based on a Butler-Volmer equation, which specifies a relationship of a current density of the battery cell with respect to a potential difference to an equilibrium potential of the battery cell.

In electrochemistry, the Butler-Volmer equation describes the reaction kinetics in the vicinity of the equilibrium potential E_{eq}. The current density j, which in electrochemistry corresponds to a reaction rate, is set by the Butler-Volmer equation in relation to the potential difference E−E_{eq}. The potential difference to the equilibrium potential is also referred to as the activation overpotential η. This equation forms the basis of the electrochemical reaction kinetics in the equilibrium between oxidation and reduction reactions.

The technical advantage is thus achieved that the charging state of the battery cell can be determined very accurately using the Butler-Volmer equation.

According to one variation of the electronic circuit, the function specifies the charging state depending on the open-circuit voltage and a temperature of the battery cell.

The technical advantage is thus achieved that an evaluation depending on the temperature is accurate, in particular for a wide temperature range in which the battery cell works.

According to one variation of the electronic circuit, the function is based on a logarithmic function that is dependent on the charging state and the temperature.

The open-circuit voltage characteristic curve of the battery cell can be described accurately via the approach with a logarithmic function.

According to one variation of the electronic circuit, the function is determined as follows:

$${U}_{O C V} ( T , S O C ) = {K}_{0} ( T ) + log ( {( ( S O C ) ( 1 - S O C ) )}^{{K}_{1} ( T )} )$$

wherein U_{OCV} (T, SOC) represents a time course of the open-circuit voltage of the battery cell, which is dependent on the temperature T and the charging state SOC, and wherein K₀(T) and K₁(T) represent temperature-dependent parameters of the battery cell.

The open-circuit voltage characteristic curve in lithium-ion cells with various cathode materials can be described accurately via this approach in the lower SOC range.

According to one variation of the electronic circuit, the analytical solution of the function is based on a derivative of the time according to the charging state.

A derivative of the time according to the charging state results in a simpler solution than a derivative of the charging state according to the time.

According to one variation of the electronic circuit, the derivative of the time according to the charging state is determined as follows:

$$\frac{dt ( S O C )}{d S O C} = \frac{{( S O C )}^{- β} {( 1 - S O C )}^{- β}}{{j}_{00} {c}_{e}^{β} sin h [ v ( {U}_{N} - {U}_{O C V} ( {K}_{0} , {K}_{1} , S O C , T ) ) ]}$$

wherein t represents the time, T the temperature, SOC the charging state, U_{OCV} the open-circuit voltage, K₀(T) and K₁(T) temperature-dependent parameters of the battery cell, cₑ an electrolyte concentration of the battery cell, j₀₀ an exchange current temperature at a standard temperature of 25° C., and β a parameter of the battery cell. In one form U_{N} may be a voltage.

The equation has a closed analytical solution, so that the time at which a certain charging state is reached can be determined accurately.

According to one variation of the electronic circuit, the electronic circuit is configured for determining the reverse function of the time dependent on the charging state based on a Newtonian method.

By using Newton's method, the reverse function can be numerically determined accurately in a simple manner and thus delivers the charging state of the battery with high accuracy.

According to one variation of the electronic circuit, the electronic circuit is configured for determining a state of power, SOP, of the battery cell based on the determined time up to which a charging state corresponding to an end point voltage of the battery cell is reached.

After the charging state of the battery cell is determined, a corresponding state of power of the battery cell can be determined in a simple manner.

The state of power (state of power, SOP) of a battery cell is defined as the ratio of peak power to rated power. The peak power based on the current conditions of the battery cell is the maximum power that can be kept constant for a given time without violating the specified design limits for battery voltage, SOC, power, and current.

According to one variation of the electronic circuit, the electronic circuit is configured for determining a current-independent internal resistance of the battery cell based on the determined charging state.

The internal resistance of the battery cell can be determined independently from the current and can therefore be specified accurately for a large range of different currents.

According to one variation of the electronic circuit, the electronic circuit is configured for generating a state observer with Kalman filter based on the analytical solution of a function and observing one or more states of the battery cell.

A dynamic determination of the charging state and corresponding state variables of the battery cell can be performed sufficiently accurately via the state observer with Kalman filter.

According to one variation of the electronic circuit, the electronic circuit is configured for determining one or more parameters of an equivalent circuit model of the battery cell based on the analytical solution of the function.

The parameters of an equivalent function model of the battery cell can also be determined very accurately via the analytical solution of the function presented here, so that the solution presented here can also be used for equivalent circuit diagram models.

According to a second aspect, the present disclosure provides a battery management system having: a controller for detecting a plurality of measured values of an open-circuit voltage of a battery cell of a battery system with corresponding time values for which the measured values of the open-circuit voltage have been detected; and an electronic circuit according to the first aspect for determining the charging state of the battery cell.

As with the electronic circuit according to the first aspect the advantage of an improved charging state determination of the battery cells of a battery system, for example, of an electric vehicle is obtained. An SOC determination with higher accuracy is possible with such a battery management system, taking into account the aging with simple calculation-saving methods.

According to a third aspect, the present disclosure provides a method for determining a charging state, SOC, of a battery cell of a battery system, in which the method comprises the following steps: obtaining a plurality of measured values of an open-circuit voltage of the battery cell with corresponding time values for which the measured values of the open-circuit voltage have been detected; determining a time up to which a charging state belonging to a predetermined end point voltage of the battery cell is reached based on an analytical solution of a function that specifies a connection between the open-circuit voltage and the charging state of the battery cell; and determining the charging state of the battery cell based on a reverse function of the time dependent from the charging state.

As with the electronic circuit according to the first aspect, with the method according to the third aspect an improved charging state determination of the battery cells of a battery system, for example, of an electric vehicle is obtained. An SOC determination with higher accuracy is possible with such a method taking into account the aging with simple, calculation-saving methods.

According to a fourth aspect, the present disclosure provides a computer program with a program code for executing the method according to the third aspect on an electronic circuit according to the first aspect or a battery management system according to the second aspect.

The technical advantage is thus achieved that the computer program can be easily carried out on a vehicle control device that can implement the real-time requirement with a neutral cost per piece without the need for additional external hardware components.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 shows a schematic block circuit diagram of an electronic circuit for determining a charging state of a battery cell of a battery system according to the present disclosure;

FIG. 2 shows a representation of a time course of the electrolyte concentration of a LiFePO₄ battery cell according to one form of the present disclosure;

FIG. 3 shows a representation of an OCV characteristic curve (equilibrium potential) of a LiFePO₄ battery cell according to one form of the present disclosure;

FIG. 4 shows a representation of the temporal change of the charging state of a LiFePO₄ battery cell according to one form of the present disclosure;

FIG. 5 shows a representation of the discharging of a fully charged LiFePO₄ battery cell according to one form of the present disclosure;

FIG. 6 shows a schematic representation of a real-time capable parameter estimator and state observer according to one form of the present disclosure; and

FIG. 7 shows a schematic representation of a method for determining a charging state of a battery cell according to the present disclosure.

The figures are only schematic depictions and serve only as an explanation of the present disclosure. Identical or identically functioning elements are consistently provided with the same reference numerals.

Reference is made in the following detailed description to the accompanying drawings that constitute a part thereof and in which specific form in which the present disclosure can be embodied are shown as illustration. It is understood that other forms can also be used, and structural or logical changes can be made without deviating from the concept of the present disclosure. The following detailed description is therefore not to be understood in a limiting sense. It is further understood that the features of the various exemplary forms described herein can be combined with one another unless it is specifically indicated otherwise.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

The aspects and variations are described with reference to the drawings, wherein identical reference numerals refer in general to the same elements. Numerous specific details are presented for explanatory purposes in the following description in order to provide a detailed understanding of one or more aspects of the present disclosure. However, it can be obvious for a person skilled in the art that one or more aspects or variations can be configured with a lower degree of the specific details. In other cases, known structures and elements are depicted in schematic form in order to facilitate the description of one or more aspects or variations. It is understood that other variations can be used, and structural or logical changes can be made without deviating from the concept of the present disclosure.

Reference is made in the following description to battery cells and

the battery management system (BMS). In order to provide that battery cells, for example, lithium-ion cells, can be operated appropriately, the cell voltages and temperatures must be continuously monitored. Monitoring of the cell voltages and temperatures is carried out via monitoring electronics, the Cell Supervision Electronics—or CSE for short. The individual cells in a battery are combined into cell modules. Each cell module has monitoring electronics, the CSE, to which the battery cells are connected. The CSE measures the voltage and the temperature of the cells.

The BMS is the central control device of a battery. The information of the individual cell monitoring, the CSEs, converges in the BMS. Based on the cell voltages, the BMS determines the current charging state (SOC=state of charge), issues the command for balancing, and takes over the communication with the vehicle. The present disclosure additionally provides that the battery cells are not overcharged or too forcefully discharged.

Reference is made to electronic circuits in the following description. An electronic circuit is a combination of electrical, and in particular electronic components (for example, diodes and transistors) into a functioning arrangement. Electronic circuits can fulfill very simple functions, such as, for example, the blinking of a lamp or the control of an automatic door. However, many complex technical devices, such as, for example, computers or electric vehicles, are also based on electronic circuits, often in the form of integrated circuits (ICs). An IC typically contains a combination of numerous mutually electrically connected electronic semiconductor components, such as transistors, diodes, and/or further active and passive components.

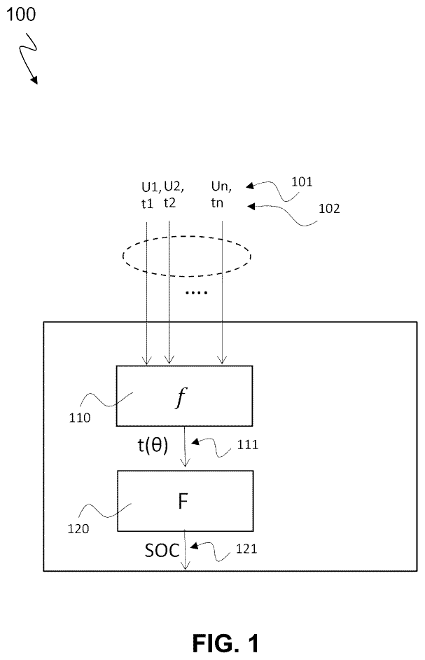

FIG. 1 shows a block circuit diagram of an electronic circuit 100 for the determining of a charging state (SOC) of a battery cell of a battery system according to the disclosure.

The electronic circuit 100 is configured for obtaining a plurality of measured values 101 of an open-circuit voltage of the battery cell with corresponding time values 102, for which the measured values 101 of the open-circuit voltage have been measured. The electronic circuit 100 can obtain the measured values 101 and the time values 102, for example, from another circuit, for example, a controller of a battery management system or a measuring sensor or a measuring circuit.

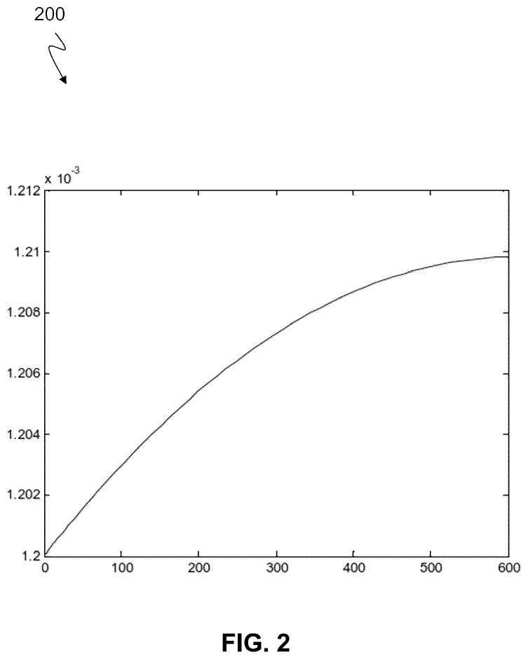

The electronic circuit 100 is configured for determining a time 111 up to which a charging state, SOC 121 belonging to an end point voltage of the battery cell is reached based on an analytical solution of a function 110, which specifies a connection between the open-circuit voltage and the charging state 121 of the battery cell. The determination is performed in the block 110, which is to show a certain processing step or processing steps. A detailed description of these processing steps is specified below, in particular with regard to FIGS. 2 to 6.

The electronic circuit 100 is configured for determining the charging state SOC 121 of the battery cell based on a reverse function 120 of the charging-state dependent time 111. The determination is performed in the block 120, which is to show a certain processing step or processing steps. A detailed description of these processing steps is also disclosed in the following for this purpose, in particular with regard to FIGS. 2 to 6.

The function 110 can be based on an electrochemical model of the battery cell, as described in more detail below with regard to FIGS. 2 to 6.

The electrochemical model of the battery cell can be set for a lower range of the charging state 121. The electrochemical model can therefore be a reduced electrochemical model of the battery cell, as shown in more detail below with regard to FIGS. 2 to 6.

The lower range of the charging state 121 can comprise, for example, charging states 121 lower than 50 percent.

The electrochemical model of the battery cell can be based on a Butler-Volmer equation, which specifies a relationship of a current density of the battery cell in relation to a potential difference to an equilibrium potential of the battery cell, as shown in detail further below.

The function 110 mentioned above can specify the charging state 121 in a manner depending on the open-circuit voltage and a temperature of the battery cell. The function 110 can be based on a logarithmic function that is dependent on the charging state 121 and the temperature.

For example, the function 110 can be determined as follows:

$${U}_{OCV} ( T , S O C ) = {K}_{0} ( T ) + log ( {( ( S O C ) ( 1 - S O C ) )}^{{K}_{1} ( T )} )$$

in which U_{OCV} (T, SOC) represents a time course of the open-circuit voltage of the battery cell, which is dependent on the temperature T and the charging state SOC 121, and in which K₀(T) and K₁(T) represent temperature-dependent parameters of the battery cell, as described in more detail below with regard to FIGS. 2 to 6.

The analytical solution of the function 110 can be based on a derivative of time according to the charging state 121, for example, as shown in the following.

The derivative of time according to the charging state 121 can be determined, for example, as follows:

$$\frac{dt ( S O C )}{d S O C} = \frac{{( S O C )}^{- β} {( 1 - S O C )}^{- β}}{{j}_{00} {c}_{e}^{β} sin h [ v ( {U}_{N} - {U}_{O C V} ( {K}_{0} , {K}_{1} , S O C , T ) ) ]}$$

in which t represents the time, T the temperature, SOC the charging state 121, U_{OCV} the open-circuit voltage, K₀(T) and K₁(T) temperature-dependent parameters of the battery cell, cₑ an electrolyte concentration of the battery cell, j₀₀ an exchange current density at a standard temperature of 25° C., and β a parameter of the battery cell. A more accurate description of this derivative of time according to the charging state 121 is found below for this purpose with regard to FIGS. 2 to 6.

The electronic circuit 100 can be configured for determining the reverse function 120 of the charging-state dependent time 111 based on a Newtonian method, as described in more detail below.

The electronic circuit 100 can be configured for determining a state of power SOP of the battery cell based on the determined time 111 up to which a charging state 121 belonging to an end point voltage of the battery cell is reached.

The electronic circuit 100 can be configured for determining a current-independent internal resistance of the battery cell based on the determined charging state 121.

The electronic circuit 100 can be configured for generating a state observer with Kalman filter based on the analytical solution of the function 110, and for observing one or more states of the battery cell.

The electronic circuit 100 can be configured for determining one or more parameters of an equivalent circuit model of the battery cell based on the analytical solution of the function 110.

The electronic circuit 100 can be used in a battery management system, for example, of a vehicle. Such a battery management system comprises, for example, a controller for detecting a plurality of measured values 101 of an open-circuit voltage of a battery cell of a battery system with corresponding time values 102 for which the measured values 101 of the open-circuit voltage have been measured; and an electronic circuit 100 as described above for determining the charging state 121 of the battery cell.

In the following is presented a solution for attaining an improvement of the standard cell model (electrochemical model) which provides an expansion of the validity range or the accuracy. The model can be solved, and a closed and analytical solution can be specified for the first time as shown in the following.

The Butler-Volmer current density is:

$${j}^{Li} ( x ) = {a}_{s} {j}_{0} ( {e}^{v η} - {e}^{- v η} )$$

Therein, a_{S} is the active surface per electrode and volume. j₀ is the exchange current density, and η is the overpotential.

The exchange current density can be written as follows:

$${j}_{0} = {j}_{00} {{k}_{T} ( {c}_{e} )}^{{a}_{a}} {( {c}_{s , max} - {c}_{se} )}^{{a}_{a}} {( {c}_{se} )}^{{a}_{c}}$$

The parameters aₐ, a_{c} are the charge transfer coefficients of the anode and cathode and can be freely selected in principle. In addition, c_{s,max} represents the maximum concentration of the solid phase (lithium-ion concentration), cₛₑ the concentration of the solid phase at the interface with the electrolytes, and cₑ the electrolyte concentration. The standard exchange current density j₀₀ is the exchange current density that sets in at standard temperature 25° C. The factor k_{T} takes into account the influence of the temperature, and at standard temperature T₀=25° C. has the value 1. The overpotential

$$η = ϕ - U$$

is obtained from the potential ϕ and the equilibrium voltage U, which is a function of the lithium concentration at the interface with the electrolytes.

The state variables such as ϕ are described by coupled partial differential equations that depend both on the location (horizontal effects) and the time. With the transition to the reduced electrochemical model used here, the location dependence x is replaced in the current density by a mean current. For the anode, for example (and correspondingly for the cathode), results that:

$${\int }_{0}^{{δ}_{n}} {j}^{Li} ( x ) dx = \frac{1}{A} = \vert {j}_{n}^{Li} \vert {δ}_{n}$$

In which δₙ is the thickness, and A is the area of the positive electrode. The assumption has been verified for a LiFePO₄ cell using a simulation with the reduced electrochemical model.

In the following, a reduced physical model is derived that is analytically solvable under certain conditions. An analytically solvable reduced physical model is currently only possible with the ECM models (½ RC) for a special solution of the inhomogeneous differential equation.

Here the parameters of the ECM model are dependent not only on temperature, but also on SOC 121.

For a simpler representation of the method, only the discharge direction is considered here. The lithium-ion concentration is not described here, but rather the charging state 121 derived therefrom. In the following, the following parameters are to be determined:

$$\begin{matrix}{j}_{00} = 2 , & {k}_{T} = 1 , & {α}_{a} = {α}_{c}\end{matrix} = β = \frac{1}{2}$$

However, these determinations, in principle, can be omitted for the method presented here, i.e., for example, charge transfer coefficients aₐ, a_{c} are freely selectable.

The following conditions are currently still constraining:

1.) Migration effects with the electrolyte concentration are not taken into account. In addition, the concentration of the electrolyte is assumed as approximately constant.

$${c}_{e} = const$$

FIG. 2 shows a representation of the temporal course 200 of the electrolyte concentration of a LiFePO₄ battery cell according to an example.

In one form, FIG. 2 shows the temporal course of the electrolyte concentration of a fully charged 16 Ah LiFePO4 cell that is discharged with 90 A up to the end point voltage. The change compared to the initial value of the concentration is 0.83%.

2.) The immediate ambient temperature or module- or cooling-temperature corresponds to the cell temperature. No thermal model is taken into account for the calculation of the cell temperature from the ambient temperature.

3.) Furthermore, the equilibrium voltages of the positive and negative electrode are replaced by the entire equilibrium voltage U_{OCV}. The equilibrium voltages for the individual electrodes are available by measurements with so-called half cells. With individual battery cells, U_{OCV} can be either measured or taken from a cell data sheet.

The decisive approach for the method is that for the lower SOC range 0% ≥SOC≤50%, the open-circuit voltage characteristic curve with lithium-ion cells with various cathode materials can be described sufficiently accurately by the following function:

$${U}_{OCV} ( T , SOC ) = {K}_{0} ( T ) + log ( {( ( SOC ) ( 1 - SOC ) )}^{{K}_{1} ( T )} )$$

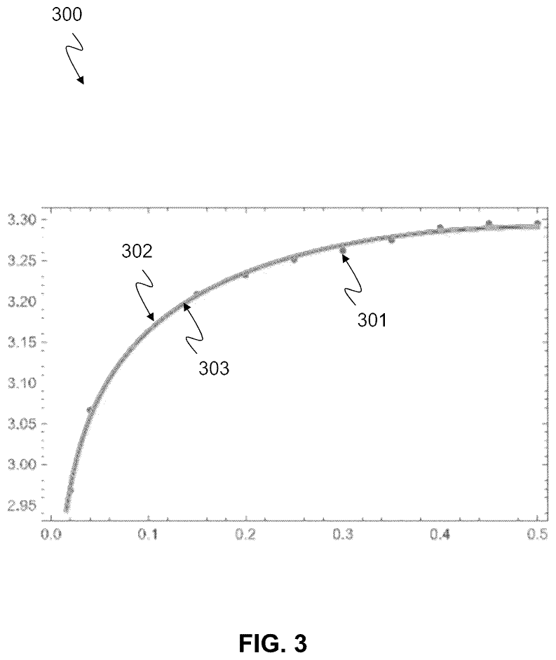

Referring to FIG. 3, a representation of an OCV characteristic curve (equilibrium potential) 300 of a LiFePO₄ battery cell according to one form of the present disclosure is shown. FIG. 3 shows the optimal fit of the function U_{OCV} with the measurement data, for example, of a lithium iron phosphate cell (LiFePO4) for the parameters

$${K}_{0} = 3.4636 \qquad {K}_{1} = 0.1246 \qquad bei 25 ° C .$$

Shown are the measurement points 301, the fit with the parameters K₀, K₁ (solid curve 302), and for a simpler representation of the complex method of the fit with the approximation of the parameter K₁ (dashed curve 303), specifically for the technology LiFePO₄, in which the aging of the OCV does not play a significant role. The method is of course also usable on any cell technology with other parameters. The parameters may still change with the aging.

The parameters K₀, K₁ of the open-circuit voltage characterization curve U_{OCV} can then be determined using the known method “regression” online in a manner depending on the aging, the charging state 121, and the temperature of the cell.

For the desired conditions and determinations, the differential equation is to be derived here for the description of state variables that can be used, in one form, for a new SOP function as well as for the Kalman filter. Finally, the solution of the differential equation shall be outlined here and describes parameters that can be represented as rational numbers, for example, K₁=p/q. However, this condition can be omitted since there is also a more general solution for parameters that can be described by real numbers of arbitrary accuracy. The condition is omitted here to simplify the representation of the complex method.

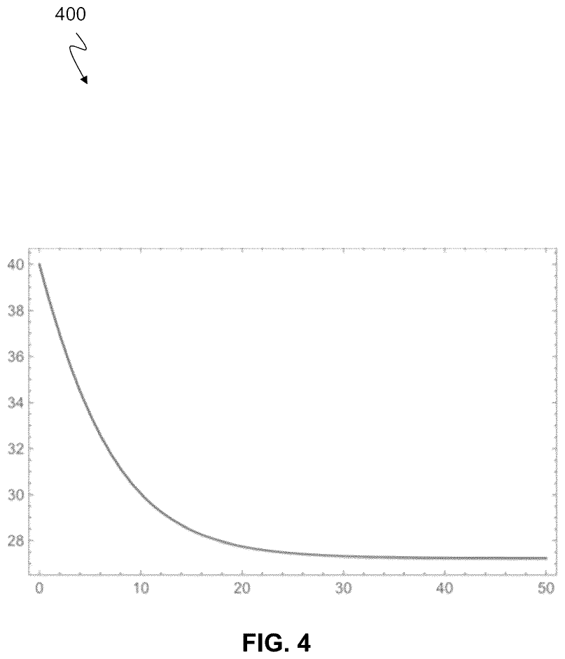

The current described by the Butler-Volmer equation, which is now dependent on the time, a specified voltage, and the SOC 121 is now considered. The Butler-Volmer equation is used in the differential equation for the temporal change of the lithium-ion concentration and the charging state 121 is used instead. After the integration is obtained the corresponding charging state for the corresponding time and voltage can be determined; see FIG. 4. FIG. 4 shows a representation of the temporal change of the charging state 400 of a LiFePO₄ battery cell according to one form of the present disclosure This description corresponds to a CCCV discharging with an unlimited current, as can be validated experimentally using a voltage-controlled discharging and corresponding load.

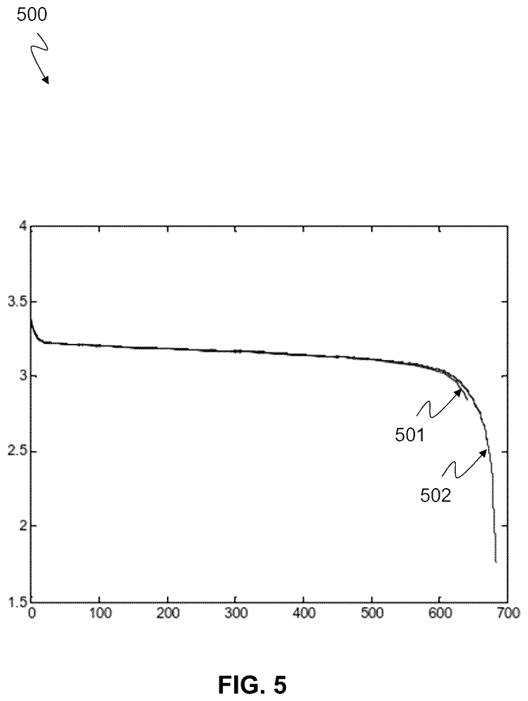

The SOC 121 is thus explicitly determined. FIG. 5 shows the corresponding result of the simulation. The transition from constant current to constant voltage can be clearly seen. A current-controlled model which is used in the numerical simulation of the reduced model can also be realized by inverting the Butler-Volmer equation. The comparison of the measured and simulated voltage for a LiFePO4 cell is shown in FIG. 5, which shows the discharging 500 of a fully charged LiFePO₄ battery cell according to an example.

The following approach is based on the voltage-controlled model and the inverse equation is considered instead of the temporal change of the charging state 400:

$$\frac{dt ( SOC )}{dSOC} = \frac{{( SOC )}^{- β} {( 1 - SOC )}^{- β}}{{j}_{00} {c}_{e}^{β} sinh [ v ( {U}_{N} - {U}_{OCV} ( {K}_{0} , {K}_{1} , SOC , T ) ) ]}$$

in which the parameter v is

$$v = {α}_{a} \frac{F}{R T}$$

F is the Faraday constant, R is the general gas constant, and aₐ is the charge transfer coefficient. The following substitution is performed in the following for the sake of simplicity: θ=SOC. The solution of this differential equation can be described by the following integral using U_{OCV}(K₀, K₁, SOC, T):

$$τ = {\int }_{{θ}_{0}}^{{θ}_{1}} \frac{{{θ}_{0} ( θ ( 1 - θ ) )}^{- β}}{( 1 - {( b θ ( 1 - θ ) )}^{κ} )} d θ - {\int }_{{θ}_{0}}^{{θ}_{1}} \frac{{( θ ( 1 - θ ) )}^{- β}}{( 1 - {( b θ ( 1 - θ ) )}^{κ} )} d θ$$

Here

$$τ = {j}_{00} {c}_{e}^{β} t \qquad κ = {K}_{1} ( T ) v \qquad b = {e}^{\frac{( {K}_{0} ( T ) - {U}_{N} )}{{K}_{1} ( T )}}$$

τ is a new time scale, the parameters b and κ are two characteristic parameters that are dependent on the temperature and aging. The individual integrals can be further simplified using elementary mathematical transformations such as, for example, the substitution of a certain integral. This is not carried out further here, since only a short version is described. In the end, the integral can be solved in a sum of four successive elementary integrals that are shown here in generalized form as follows:

$${\int }_{0}^{∞} \frac{{x}^{λ - 1}}{{( 1 + x )}^{μ}} S [ 〈 \begin{matrix}[ \begin{matrix}p , & o \\ A - p , & B\end{matrix} ] \\ ( \begin{matrix}q , & r \\ C - q , & D - r\end{matrix} ) \\ ( \begin{matrix}k , & l \\ E - k , & F - l\end{matrix} )\end{matrix} \vert \begin{matrix}( a ) ; ( b ) \\ ( c ) ; ( d ) \\ ( e ) ; ( f )\end{matrix} \vert \begin{matrix}υ {\{ \frac{x}{1 + x} \}}^{Q} \\ ω {\{ \frac{x}{1 + x} \}}^{Q}\end{matrix} 〉 ] dx = \frac{Γ ( μ - λ )}{{ϱ}^{( μ - λ )}} S [ [ 〈 \begin{matrix}[ \begin{matrix}p + ϱ , & o \\ A - p , & B + ϱ\end{matrix} ] \\ ( \begin{matrix}q , & r \\ C - q , & D - r\end{matrix} ) \\ ( \begin{matrix}k , & l \\ E - k , & F - l\end{matrix} )\end{matrix} \vert \begin{matrix}Δ ( ϱ , λ ) , ( a ) ; Δ ( ϱ , μ ) , ( b ) \\ ( c ) ; ( d ) \\ ( e ) ; ( f )\end{matrix} \vert \begin{matrix}υ \\ ω\end{matrix} 〉 ]$$

as described in “Shah, M .: ‘On generalization of some results and their applications’ Collectanea Mathematica, 1973, 24, (3), pp. 249-266”. The function is a generalization of Meijer's G-function that has been implemented by SHARMA as follows:

$$S [ \begin{matrix}x \\ y\end{matrix} ] = S [ 〈 \begin{matrix}[ \begin{matrix}b , & o \\ A - p , & B\end{matrix} ] \\ ( \begin{matrix}q , & r \\ C - q , & D - r\end{matrix} ) \\ ( \begin{matrix}k , & l \\ E - k , & F - l\end{matrix} )\end{matrix} \vert \begin{matrix}( a ) ; ( b ) \\ ( c ) ; ( d ) \\ ( e ) ; ( f )\end{matrix} \vert \begin{matrix}x \\ y\end{matrix} 〉 ] = \frac{1}{{( 2 π i )}^{2}} {\int }_{{L}_{1}} {\int }_{{L}_{2}} Φ ( ξ + η ) Ψ ( ξ , η ) {x}^{ξ} {y}^{η} d ξ d η$$

in which the following applies:
(i) A, B, C, etc. are non-negative integers and satisfy the following inequalities:
D≥1, F≥1, A≥1, B≥1, o≤q≤C, o≤k≤E,
o≤r≤D, o≤l≤F, A+C≤B+D and A+E≤B+F
(ii) the notation (a) stands for a set of A parameters
a₁, a₂, . . . , aₚ; aₚ₊₁, . . . aₐ
with the same meaning for (b) (c) (d) (e) and (f);
(iii) L₁ and L₂ are fitting contours
(iv)

$$Δ ( ϱ , λ ) = \frac{λ}{ϱ} , \frac{λ + 1}{ϱ} , … , \frac{λ + ϱ - 1}{ϱ}$$

This derivative has the advantage that Shah has already published a mathematical proof. Alternatively, a separate derivative was originally deduced by the author, which, however, is very complex in its representation. The numerical calculation has already been published as EGBMGF function but could not be validated by the author. There is a different definition in the original of R. P. Agarwal 1964, that can be transferred into that of SHARMA with “integration—Definite integral involving algebraic, exponential, and product of two Meijer's G function—Mathematics Stack Exchange”. The definition was published and verified in “Extended Generalized Bivariate Meijer G-Function results don't match?—Online Technical Discussion Groups-Wolfram Community”.

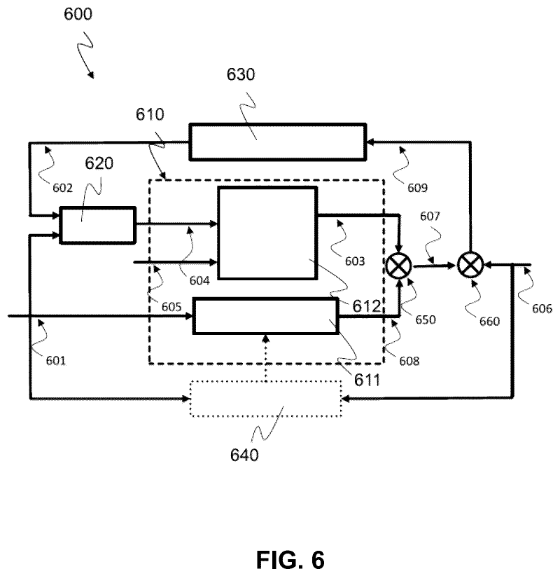

FIG. 6 shows a schematic representation of a real-time capable parameter estimator and state observer 600 according to one variation.

An open-circuit voltage characteristic 610 includes two blocks 612 and 611. The first block 612 describes a predetermined characteristic curve, which determines the open-circuit voltage U_{OCV}(tₙ) 603 from the two inputs charging state, SOC (tₙ) 604 and temperature T(tₙ) 605. The second block 611 describes the dynamic cell model, which determines the voltage output U_{OCV}(tₙ) 608 from the current input I(tₙ), 601. Both voltage outputs 608 and 603 are combined 650 with each other, in order to determine the simulated voltage U_{SIM}(tₙ) 607 at time tₙ. The simulated voltage U_{SIM}(tₙ) 607 is compared 660 to the measured voltage U_{MESS}(tₙ), 606, at time tₙ, in order to obtain a difference voltage 609 at time tₙ. This difference voltage 609 is processed by the adaptive Kalman filter 630 to obtain the optimal charging state SOCₒₚₜ(tₙ₋₁), 602, at the time tₙ₋₁. In the block 620 “Coulomb counting,” the charging state SOCₒₚₜ(tₙ), 604, at the time tₙ is determined from the optimal charging state SOCₒₚₜ(tₙ₋₁), 602, at the time tₙ₋₁ and the current input I(tₙ) 601 using “Coulomb counting.” An optional parameter estimator 640 can be used to adjust the parameters of the dynamic cell model 611 online. The current input I(tₙ) 601 and the measured voltage U_{MESS}(tₙ), 606, at time tₙ serve as inputs for the parameter estimator 640.

FIG. 6 shows the general diagram of the reduced electrochemical model and the interaction of two algorithms, the parameter estimator and the adaptive extended Kalman filter, which can be developed based on the function described above.

The parameters of the function are stored in a table depending on the temperature. However, since the parameters can also change with aging after a certain time, for example, each month, the parameters must be redetermined either using a parameter estimator directly on the microcontroller or offline using a cloud connection (for example, BMS2Cloud). In the first case, due to the lower number of freely selectable parameters in the reduced model, and due to the existence of the closed solution, the parameter determination is less time and calculation intensive. In other publications, in which a physical dynamic cell model is used with the Kalman filter for the construction of a state observer, the dependence of the parameters on aging is specifically indicated, the parameter estimator is not considered at all but due to the complexity. An aging-related parameter adjustment of the physical model is carried out with the digital twins.

The solution of the integral

$$t ( θ ) = f \{ S [ \begin{matrix}{υθ}^{ϱ} \\ {ωθ}^{ϱ}\end{matrix} ] \}$$

delivers the time t up until which a charging state for a certain lower end point voltage is reached. The reverse function

$$θ ( t ) = {f}^{- 1} \{ S [ \begin{matrix}{υθ}^{ϱ} \\ {βω}^{ϱ}\end{matrix} ] \} := F ( t )$$

can be determined numerically using Newton's method and delivers the charging state of the battery. With the help of the function F(t), both the voltage in the CC and the current in the CV (limit current) can be determined.

The function F(t) was previously unknown. An improved understanding of the properties of the function with the help of a mathematical toolbox (series development, etc.) was developed. The development makes possible numerous innovations, such as, for example, comparing the derivative to the model of an n-RC ECM model and deriving conclusions between the ECM parameters and the parameters of the EM therefrom. The solution t(θ) already provides valuable information and can be used as SOP function in the described manner. A variety of applications can be summarized as follows:

1) Establishing SOP function and Kalman filter based on t(θ). The time can be calculated directly for any values of θ. In contrast with other known solutions, the model need not be simulated in a certain state with the interval Δh. t(θ) provides additional information here about the characteristic behavior of the cell/battery.

2) Using the function t(θ) for an aging-dependent parameter determination. Other known solutions are very calculation intensive, and the implementation on a control device is rarely practicable.

3) Determining θ(t) via a Newtonian method, calculating the simulated current, and using it in a Kalman filter and SOP function. A voltage-controlled solution is not known here.

4) Determining θ(t) via a Newtonian method, calculating the simulated voltage, and using it in a Kalman filter delivers a high accuracy due to the electrochemical model, with simultaneously low calculation and memory requirements.

5) Determining θ(t) via a Newtonian method. Determining a current-independent internal resistance at any lower end point voltage with the help of the calculated current and the calculated voltage.

6) Comparing the new analytical model to the known ECM model to thus obtain conclusions about the SOC-dependent ECM parameters.

The function t(θ) delivers new information about the state of the cells/battery, which can be used for the evaluation of the aging.

The method presented here delivers some advantages in comparison to the known solutions with regard to low memory and calculation intensive methods with simultaneously high SOC accuracy for the SOC determination.

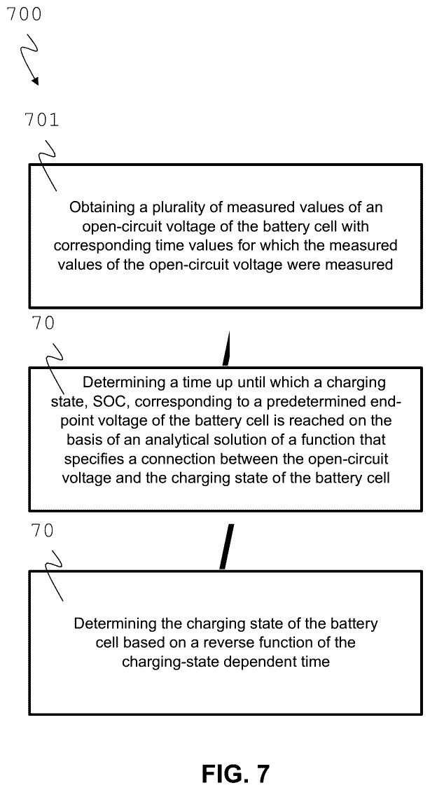

FIG. 7 shows a schematic representation of a method 700 for determining a charging state 121 of a battery cell of a battery system according to the disclosure. The battery system can be, for example, a battery system of an electric vehicle.

The method 700 comprises the following steps: obtaining 701 a plurality of measured values 101 of an open-circuit voltage of the battery cell with corresponding time values 102, for which the measured values 101 of the open-circuit voltage have been measured; determining 702 a time 111 up to which a charging state, SOC 121, corresponding to a specified end point voltage of the battery cell is reached on the basis of an analytical solution of a function 110 which specifies a connection between the open-circuit voltage and the charging state 121 of the battery cell; and determining 703 the charging state 121 of the battery cell based on a reverse function 120 of the charging-state-dependent time 111.

A computer program with a program code for executing the method 700 can furthermore be provided on an electronic circuit 100 or a battery management system, as described above with regard to FIG. 1.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. An electronic circuit for determining a charging state of a battery cell of a battery system, wherein the electronic circuit is configured for:
obtaining a plurality of measured values of an open-circuit voltage of the battery cell with corresponding time values for which the measured values of the open-circuit voltage have been detected;
determining a time up to which a charging state corresponding to an end point voltage of the battery cell is reached based on an analytical solution of a function that specifies a connection between the open-circuit voltage and the charging state of the battery cell; and
determining the charging state of the battery cell based on a reverse function of the time.

2. The electronic circuit according to claim 1, wherein the function is based on an electrochemical model of the battery cell.

3. The electronic circuit according to claim 2, wherein the electrochemical model of the battery cell is set for a lower range of the charging state.

4. The electronic circuit according to claim 3, wherein the lower range of the charging state comprises charging states lower than 50 percent.

5. The electronic circuit according to claim 2, wherein the electrochemical model of the battery cell is based on a Butler-Volmer equation, which specifies a relationship of a current density of the battery cell in relation to a potential difference to an equilibrium potential of the battery cell.

6. The electronic circuit according to claim 1, wherein the function specifies the charging state depending on the open-circuit voltage and a temperature of the battery cell.

7. The electronic circuit according to claim 1, wherein the function is based on a logarithmic function that is dependent on the charging state and a temperature.

8. The electronic circuit according to claim 7, wherein the function is determined as follows:
$${U}_{OCV} ( T , SOC ) = {K}_{0} ( T ) + log ( {( ( SOC ) ( 1 - SOC ) )}^{{K}_{1} ( T )} ) ,$$
wherein U_{OCV} (T, SOC) represents a time course of the open-circuit voltage of the battery cell, which is dependent on the temperature represented as T and the charging state represented as SOC, and K₀(T) and K₁(T) represent temperature-dependent parameters of the battery cell.

9. The electronic circuit according to claim 1, wherein the analytical solution of the function is based on a derivative of time according to the charging state.

10. The electronic circuit according to claim 9,
wherein the derivative of time according to the charging state is determined as follows:
$$\frac{dt ( SOC )}{dSOC} = \frac{{( SOC )}^{- β} {( 1 - SOC )}^{- β}}{{j}_{00} {c}_{e}^{β} sinh [ v ( {U}_{N} - {U}_{OCV} ( {K}_{0} , {K}_{1} , SOC , T ) ) ]} ,$$
wherein t represents the time, T a temperature, SOC the charging state, U_{OCV} the open-circuit voltage, K₀(T) and K₁(T) temperature-dependent parameters of the battery cell, cₑ an electrolyte concentration of the battery cell, j₀₀ an exchange current temperature at a standard temperature of 25° ° C., and β a parameter of the battery cell.

11. The electronic circuit according to claim 1, wherein the electronic circuit is configured for determining the reverse function of the time based on a Newtonian method.

12. The electronic circuit according to claim 1, wherein the electronic circuit is configured for determining a state of power, SOP, of the battery cell based on the determined time up until which a charging state corresponding to the end point voltage of the battery cell is reached.

13. The electronic circuit according to claim 1, wherein the electronic circuit is configured for determining a current-independent internal resistance of the battery cell based on the determined charging state.

14. The electronic circuit according to claim 1, wherein the electronic circuit is configured for generating a state observer with a Kalman filter and to observe one or more states of the battery cell based on the analytical solution of the function.

15. The electronic circuit according to claim 1, wherein the electronic circuit is configured for determining one or more parameters of an equivalent circuit model of the battery cell based on the analytical solution of the function.

16. A battery management system having:
a controller for detecting a plurality of measured values of an open-circuit voltage of a battery cell of a battery system with corresponding time values for which the measured values of the open-circuit voltage have been measured; and
an electronic circuit according to claim 1 for determining the charging state of the battery cell.

17. A method for determining a charging state of a battery cell of a battery system, wherein the method includes:
obtaining a plurality of measured values of an open-circuit voltage of the battery cell with corresponding time values for which the measured values of the open-circuit voltage have been measured;
determining a time up until which a charging state corresponding to a specified end point voltage of the battery cell is reached based on an analytical solution of a function which specifies a connection between the open-circuit voltage and the charging state of the battery cell; and
determining the charging state of the battery cell based on a reverse function of the time.
